(19) United States
(12) Patent Application Publication
(10) Pub. No.: US 2026/0173853 A1
(43) Pub. Date: Jun. 18, 2026

(54) SEMICONDUCTOR DEVICE AND METHOD FOR FORMING THE SAME

(71) Applicant: Winbond Electronics Corp., Taichung City (TW)

(72) Inventors: Ping-Lung YU, Hsinchu City (TW); Po-Chun SHAO, Hsinchu City (TW)

(21) Appl. No.: 19/323,494

(22) Filed: Sep. 9, 2025

(30) Foreign Application Priority Data
Dec. 12, 2024 (TW) 113148281

(51) Int. Cl. H01L 23/528; H01L 21/3115; H01L 21/768; H01L 23/522; H01L 23/532

(52) U.S. Cl. CPC H10W 20/435; H10P 30/40; H10W 20/034; H10W 20/042; H10W 20/059; H10W 20/076; H10W 20/095; H10W 20/425; H10W 20/48; H10W 20/498

(57) ABSTRACT

A semiconductor device and a method for forming the same are provided. The formation method includes providing a base layer. A trench is formed in the base layer. An implantation process is performed on the base layer to form a first barrier layer on a side surface of the trench. A second barrier layer is formed on the first barrier layer and on a bottom surface of the trench. A seed layer is formed on the second barrier layer. A conductive pillar is formed on the seed layer.

### CROSS REFERENCE TO RELATED APPLICATIONS

This application claims priority of Taiwan patent application No. 113148281, filed on Dec. 12, 2024, the entirety of which is incorporated by reference herein.

### TECHNICAL FIELD

The present disclosure relates to a semiconductor device and a method for forming the same, and, in particular, it relates to a semiconductor device that includes a barrier layer and/or a seed layer, and a method for forming the semiconductor device.

### BACKGROUND

In the trend of semiconductor device miniaturization, the size of each component continues to decrease to improve performance. Since each component in a semiconductor device may affect other components, for example, due to the influence of diffusion, unnecessary conduction, leakage current, and/or short circuit may occur between adjacent components. Furthermore, since the size of each component in a semiconductor device is small, it is difficult to form the component, resulting in the problems of component discontinuity or damage.

### BRIEF SUMMARY

The present disclosure prevents metal atoms from diffusing into adjacent components by disposing a double barrier layer on a conductive structure. Therefore, the double barrier layer of the present disclosure can prevent unnecessary conduction, leakage current, and/or short circuits between adjacent components. Furthermore, the present disclosure forms a target layer on a seed layer and performs a re-sputtering process on the target layer to transfer the target material from the target layer into the trench. Therefore, the target material transferred into the trench can improve the continuity and/or reliability of the seed layer. Therefore, the present disclosure can improve the electrical properties of the semiconductor device and improve the process margin (window) of the method for forming the semiconductor device.

An embodiment of the present disclosure provides a method for forming a semiconductor device. The formation method includes providing a base layer. A trench is formed in the base layer. An implantation process is performed on the base layer to form a first barrier layer on a side surface of the trench. A second barrier layer is formed on the first barrier layer and on a bottom surface of the trench. A seed layer is formed on the second barrier layer. A conductive pillar is formed on the seed layer.

An embodiment of the present disclosure provides a semiconductor device. The semiconductor device includes a base layer, a conductive structure, a first barrier layer, a second barrier layer, a seed layer, and a conductive pillar. The conductive structure is disposed in the base layer. The first barrier layer is disposed in the base layer and on a portion of a top surface of the conductive structure. The second barrier layer is disposed in the base layer, disposed on the first barrier layer, and disposed on a remaining portion of the top surface of the conductive structure. The seed layer is disposed on the second barrier layer. The conductive pillar is disposed on the seed layer.

### BRIEF DESCRIPTION OF THE DRAWINGS

FIGS. 1 to 17 are cross-sectional views of various stages of a method for forming a semiconductor device according to some embodiment of the present disclosure, respectively.

### DETAILED DESCRIPTION

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (height/thickness direction). In some embodiments, the schematic cross-sectional views described herein are schematic views of the XZ plane, and a normal direction of a substrate is the third direction D3.

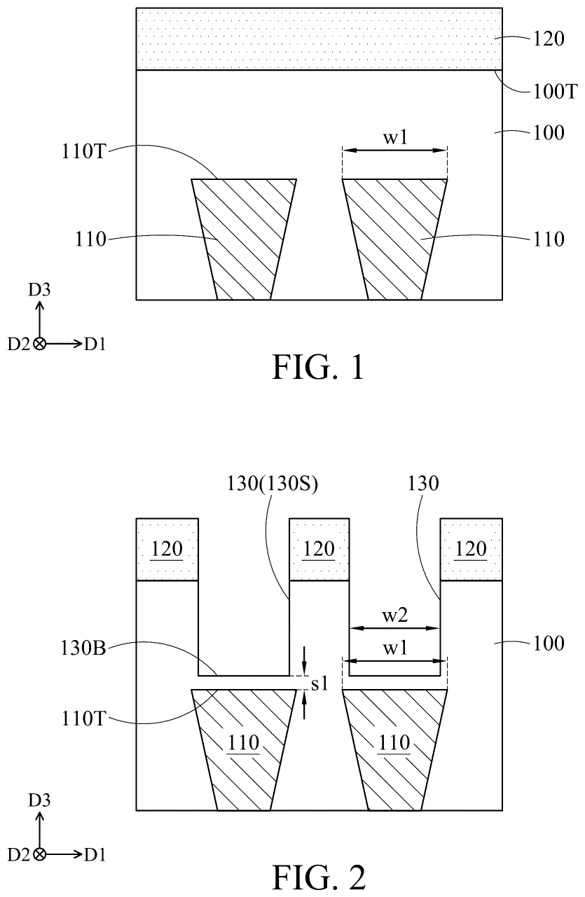

Referring to FIG. 1, a base layer 100 may be provided. The base layer 100 may include a dielectric material such as an oxide. The base layer 100 may include silicon oxide, but the present disclosure is not limited thereto. In some embodiments, a conductive structure 110 may be provided in the base layer 100. The conductive structure 110 may include polycrystalline silicon; amorphous silicon; a metal, such as tungsten (W), copper (Cu), silver (Ag), gold (Au), cobalt (Co); a conductive metal oxide; a conductive metal nitride, such as tungsten nitride (WN), titanium nitride (TiN); a conductive metal carbide, such as titanium carbide (TiC); other suitable materials, or a combination thereof, but the present disclosure is not limited thereto. The conductive structure 110 may be a conductive plug, a conductive contact, or the like. The top surface 110T of the conductive structure 110 may be lower than the top surface 100T of the base layer 100. The conductive structure 110 may be buried in the base layer 100. In some embodiments, the conductive structure 110 may have a profile that is wide at the top surface and narrow at the bottom surface, but the present disclosure is not limited thereto. In other embodiments, the conductive structure 110 may have a rectangular (same width at the top surface and the bottom surface), a regular trapezoid (narrow at the top surface and wide at the bottom surface), or other profiles. In some embodiments, in the first direction D1, the top surface 110T of the conductive structure 110 may have a first width w1. In some embodiments, a photoresist layer 120 may be formed on the base layer 100. In other embodiments (not shown), the conductive structure 110 may be omitted.

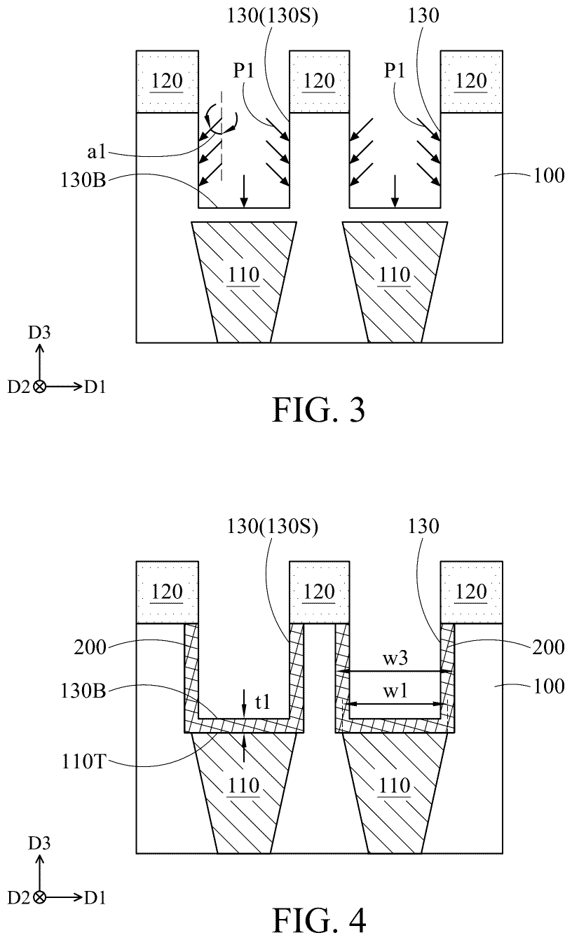

Referring to FIG. 2, the photoresist layer 120 may be patterned to form an opening (not shown) in the photoresist layer 120. An etching process may be performed by using the patterned photoresist layer 120 as an etching mask to form a trench 130 in the base layer 100. The etching process may be a dry etching process. The trench 130 may correspond to the conductive structure 110. The trench 130 may be located directly above the conductive structure 110. In the normal direction (third direction D3) of the base layer 100, the bottom surface 130B of the trench 130 may be spaced apart from the top surface 110T of the conductive structure 110 by a first distance s1. A portion of the base layer 100 may be between the trench 130 and the conductive structure 110. The first distance s1 may be greater than or equal to 1 nm and less than or equal to 30 nm. For example, the first distance s1 may be 1 nm, 5 nm, 10 nm, 15 nm, 20 nm, 25 nm, 30 nm, or any value or any range of values between the aforementioned values, but the present disclosure is not limited thereto. Accordingly, it is possible to prevent the subsequent implantation process (for example, the implantation process P1 shown in FIG. 3) from damaging the conductive structure 110. In detail, when the base layer 100 covers the top surface 110T of the conductive structure 110, it is possible to prevent the dopants of the implantation process from entering the conductive structure 110, thereby preventing the electrical properties of the conductive structure 110 from being degraded.

As shown in FIG. 2, the implantation depth of the implantation process to be performed subsequently may correspond to the first distance s1, and thus the first distance s1 may correspond to the first thickness of the subsequently formed first barrier layer (for example, the first thickness t1 of the first barrier layer 200 shown in FIG. 4). For example, the first distance s1 may be equal to the first thickness of the first barrier layer. Accordingly, by spacing the bottom surface 130B of the trench 130 and the top surface 110T of the conductive structure 110 apart from each other, a position for the subsequent formation of the first barrier layer may be remained (reserved).

As shown in FIG. 2, in the first direction D1, the trench 130 may have a second width w2, and the first width w1 of the conductive structure 110 may be greater than the second width w2 of the trench 130. In addition, by controlling the second width w2 of the trench 130, the second width w2 of the trench 130 may be prevented from being too large, thereby preventing leakage current from being generated between adjacent trenches 130. In some embodiments, the difference between the first width w1 and the second width w2 may correspond to the first thickness of the subsequently formed first barrier layer (for example, the first thickness t1 of the first barrier layer 200 in FIG. 4). For example, the difference between the first width w1 and the second width w2 may be less than or equal to the first thickness of the first barrier layer. Accordingly, by controlling the second width w2 of the trench 130, a position for the subsequent formation of the first barrier layer may be reserved, but the present disclosure is not limited thereto.

Referring to FIG. 3, an implantation process P1 may be performed on the base layer 100. In some embodiments, the implantation process P1 may be an ion implantation process (IMP), a plasma process, a surface treatment process, other suitable processes, or a combination thereof. In some embodiments, the implantation angle a1 of the implantation process P1 may be 0 to 45 degrees. Wherein, the implantation angle a1 may be the angle between the traveling direction of the ion beam and the normal direction of the base layer 100. In some embodiments, the implantation angle a1 may be 0 degrees, 5 degrees, 10 degrees, 15 degrees, 20 degrees, 25 degrees, 30 degrees, 35 degrees, 40 degrees, 45 degrees, or any value or any range of values between the aforementioned values, but the present disclosure is not limited thereto. In some embodiments, the implantation angle a1 for the side surface 130S of the trench 130 may be different from the implantation angle a1 for the bottom surface 130B of the trench 130. In some embodiments, the implantation process P1 may use dopants, and the dopants may be nitrogen (N) atoms, carbon (C) atoms, or a combination thereof. There may be no angle restriction for the plasma process and the surface treatment process.

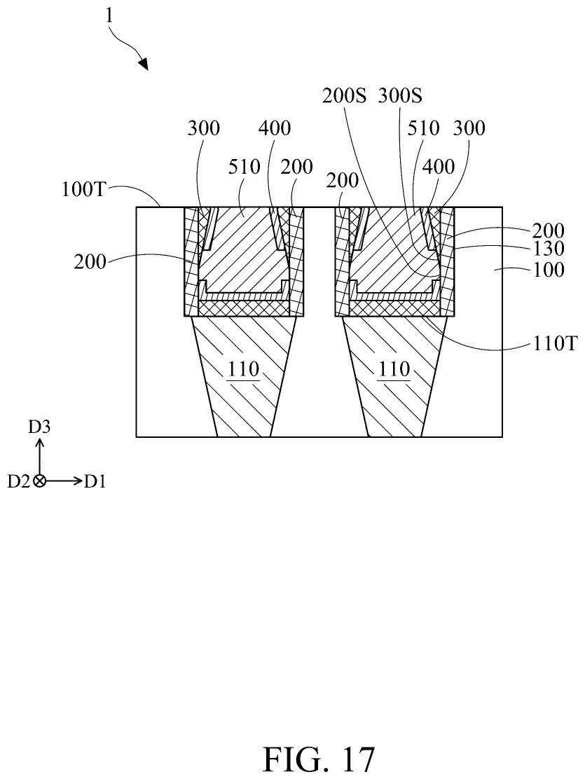

Referring to FIG. 4, after performing an implantation process P1 on the base layer 100, a first barrier layer 200 may be formed on the side surface 130S and the bottom surface 130B of the trench 130. Therefore, the first barrier layer 200 may include a nitride, a carbide, or a carbonitride of the base layer 100. For example, the base layer 100 may include silicon oxide, and the first barrier layer 200 may include silicon nitride, silicon oxynitride, silicon oxycarbide, or silicon oxycarbonitride. In some embodiments, the first barrier layer 200 may have a concentration gradient. For example, the first barrier layer 200 closer to the ion beam or plasma beam of the implantation process P1 has a higher dopant concentration. For example, the dopant concentration at the covered surface of the first barrier layer 200 covered by the base layer 100 may be less than that at the exposed surface of the first barrier layer 200 exposed by the base layer 100. For example, the dopant concentration at the covered surface of the first barrier layer 200 covered by the conductive structure 110 may be lower than that at the exposed surface of the first barrier layer 200 exposed by the conductive structure 110. Accordingly, the concentration gradient of the first barrier layer 200 can effectively prevent the metal atoms in the subsequently formed conductive pillars (for example, the conductive pillars 510 in FIG. 17) from diffusing into the conductive structure 110 and/or the base layer 100 to prevent electrical degradation. In detail, since the subsequently formed conductive pillars may be closer to the exposed surface of the first barrier layer 200, when the dopant concentration at the exposed surface of the first barrier layer 200 may be higher, it can better prevent the metal atoms in the conductive pillars from diffusing into the conductive structure 110 and/or the base layer 100.

As shown in FIG. 4, the first barrier layer 200 may have a shape corresponding to the trench 130. In the third direction D3, the first barrier layer 200 may have a first thickness t1. In the first direction D1, the first barrier layer 200 may have a third width w3, and the third width w3 may be greater than the first width w1 of the conductive structure 110. Accordingly, the first barrier layer 200 may effectively prevent metal atoms in the conductive pillar from diffusing into the conductive structure 110 and/or the base layer 100.

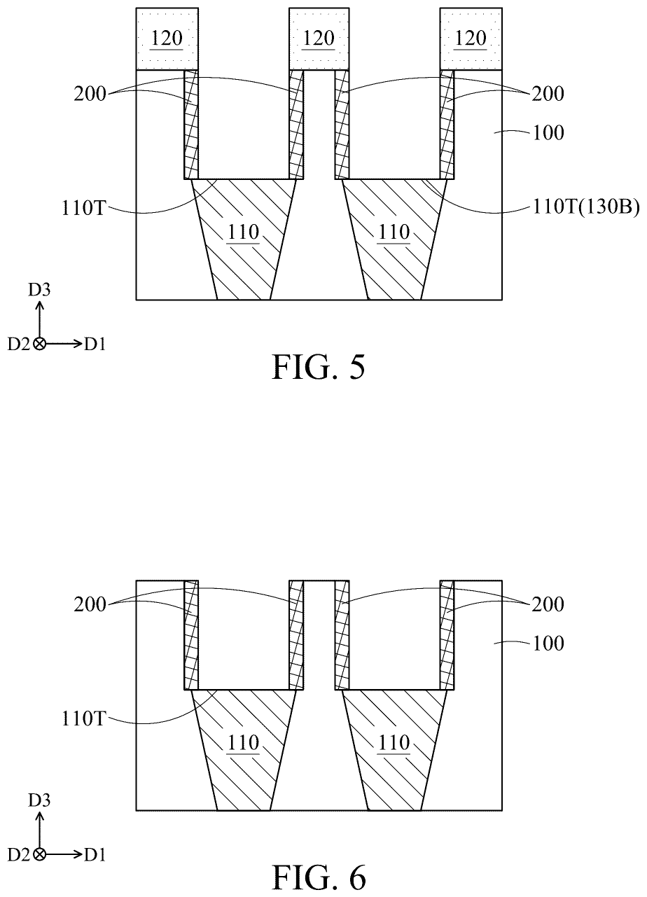

Referring to FIG. 5, an etching process may be performed by using the patterned photoresist layer 120 as an etching mask to remove the first barrier layer 200 located on the bottom surface 130B of the trench 130, thereby exposing the bottom surface 130B of the trench 130. The etching process may be a dry etching process. The first barrier layer 200 may be disposed on a portion of the top surface 110T of the conductive structure 110, and the first barrier layer 200 may expose the remaining portion of the top surface 110T of the conductive structure 110.

Referring to FIG. 6, the patterned photoresist layer 120 may be removed by a removal process such as an ashing process, thereby exposing the first barrier layer 200 and the base layer 100.

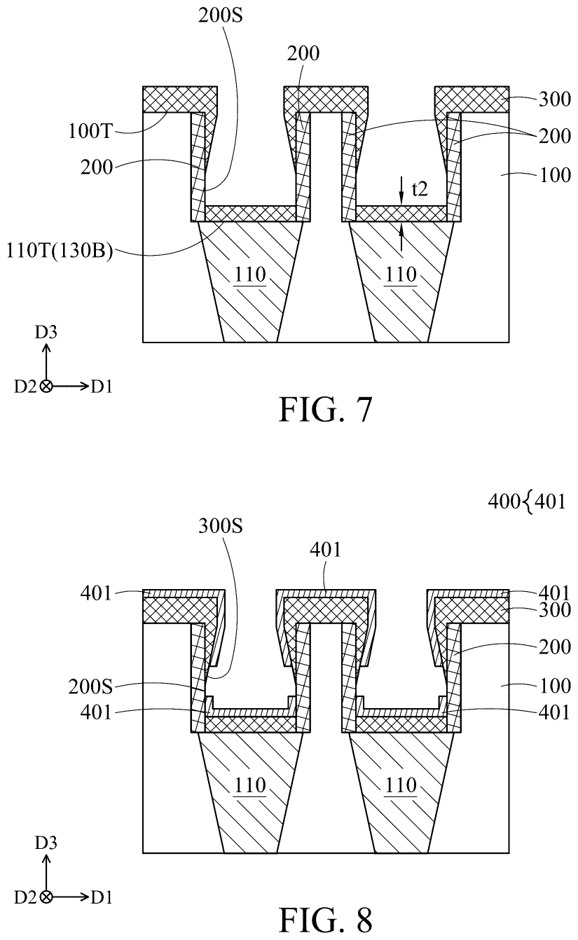

Referring to FIG. 7, the second barrier layer 300 may be formed on the first barrier layer 200, the second barrier layer 300 may be formed on the bottom surface 130B of the trench 130, and the second barrier layer 300 may be formed on the top surface 100T of the base layer 100. The second barrier layer 300 may be formed by a deposition process. The deposition process may include a physical vapor deposition (PVD), a chemical vapor deposition (CVD), an atomic layer deposition (ALD), other suitable deposition processes, or a combination thereof, but the present disclosure is not limited thereto. For example, the PVD may be used to form the second barrier layer 300. The second barrier layer 300 may include a metal, a conductive metal nitride, or a conductive metal carbide. The second barrier layer 300 may include Ta, W, Ti, and compounds thereof. For example, the second barrier layer 300 may include Ta, TaN, Ti, TiN, TiC, W₂N, WN, TaSiN, but the present disclosure is not limited thereto.

As shown in FIG. 7, in some embodiments, the second barrier layer 300 may be disposed discontinuously. For example, the second barrier layer 300 may preferentially be continuously disposed in the horizontal direction, rather than in vertical direction. The second barrier layer 300 disposed on the first barrier layer 200 may be physically separated from the second barrier layer 300 disposed on the top surface 110T of the conductive structure 110. The second barrier layer 300 may cover a portion of the side surface 200S of the first barrier layer 200, and the second barrier layer 300 may expose the remaining portion of the side surface 200S of the first barrier layer 200. In other embodiments (not shown), the second barrier layer 300 may be disposed on the first barrier layer 200 in different patterns, and the second barrier layer 300 may expose at least a portion of the side surface 200S of the first barrier layer 200. The first barrier layer 200 may be located between the second barrier layer 300 and the base layer 100. Since the first barrier layer 200 may be in contact with and connect the second barrier layers 300 which are separated from each other, a double barrier layer including the first barrier layer 200 and the second barrier layer 300 may be formed. Accordingly, by disposing the double barrier layer, metal atoms in the subsequently formed conductive pillars can be effectively prevented from diffusing into the conductive structure 110 and/or the base layer 100 to prevent electrical degradation. Furthermore, the double barrier layer can overcome the limitation that it is difficult to continuously form the first barrier layer 200 and/or the second barrier layer 300, so the double barrier layer can be widely used in trenches with different aspect ratios.

As shown in FIG. 7, the first barrier layer 200 may be disposed on a portion of the top surface 110T of the conductive structure 110, and the second barrier layer 300 may be disposed on the remaining portion of the top surface 110T of the conductive structure 110. Accordingly, since the second barrier layer 300 may be in contact with the top surface 110T of the conductive structure 110, and the second barrier layer 300 includes a metal, a conductive metal nitride, or a conductive metal carbide, the conductive resistance between the conductive structure 110, the second barrier layer 300, and the conductive pillar formed subsequently may be reduced. In the normal direction of the base layer 100, the second barrier layer 300 located on the top surface 110T of the conductive structure 110 may have a second thickness t2. The second thickness t2 may be greater than or equal to 3 nm to provide a sufficient blocking effect. The second thickness t2 may be less than or equal to 1000 nm to prevent the second barrier layer 300 located on the top surface 100T of the base layer 100 from being connected to each other and sealing prematurely. In some embodiments, when the semiconductor device may be applied to a memory device, the second thickness t2 may be greater than or equal to 1 nm and less than or equal to 2.5 nm. For example, the second thickness t2 may be 1 nm, 1.5 nm, 2 nm, 2.5 nm, or any value or any range of values between the aforementioned values, but the present disclosure is not limited thereto.

Referring to FIG. 8, a seed layer 400 may be formed on the second barrier layer 300. The seed layer 400 may be formed by an electroplating process, a PVD process, a CVD process, other suitable processes or a combination thereof. The material of the seed layer 400 and the material of the subsequently formed conductive pillar may be the same or different. The material of the seed layer 400 and the material of the subsequently formed conductive pillar may have good compatibility. The seed layer 400 may include a metal such as tungsten (W), copper (Cu), silver (Ag), gold (Au), cobalt (Co). For example, the seed layer 400 may include copper. In some embodiments, the seed layer 400 may expose the side surface 200S of the first barrier layer 200. In some embodiments, the seed layer 400 may cover a portion of the side surface 300S of the second barrier layer 300 and may expose the remaining portion of the side surface 300S of the second barrier layer 300. In some other embodiments, the seed layer 400 may completely cover the side surface 300S of the second barrier layer 300.

As shown in FIG. 8, the seed layer 400 may be discontinuously formed on the second barrier layer 300. The seed layer 400 may include a plurality of sub-portions 401, and each of the sub-portions 401 may be physically separated from each other. In other embodiments (not shown), the seed layer 400 may be continuously formed on the second barrier layer 300 and the first barrier layer 200, and the seed layer 400 may not expose the side surface 300S of the second barrier layer 300 and may not expose the side surface 200S of the first barrier layer 200.

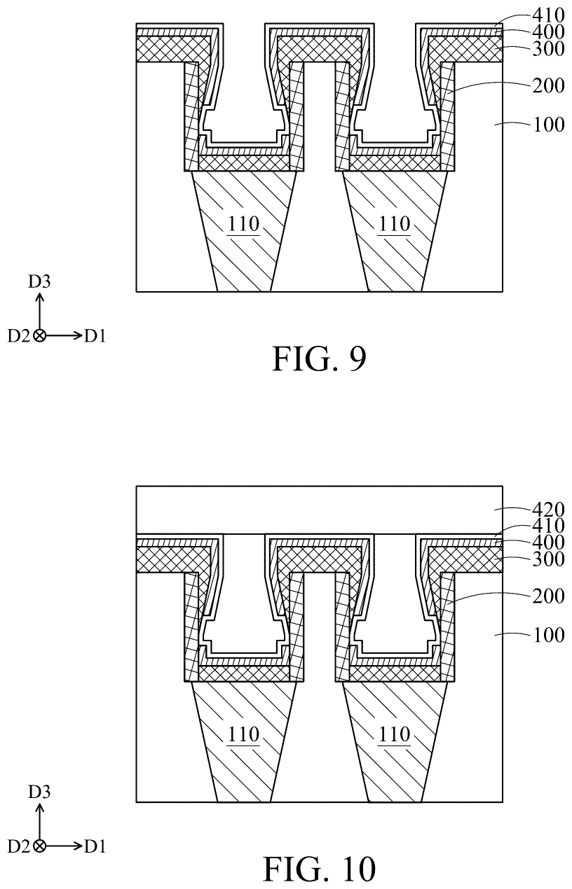

Referring to FIG. 9, a liner 410 may be conformally formed on the seed layer 400, the second barrier layer 300, and the first barrier layer 200. The liner 410 may be formed by an ALD process. The liner 410 may include an oxide such as silicon oxide, a nitride such as silicon nitride, an oxynitride such as silicon oxynitride, the like, or a combination thereof, but the present disclosure is not limited thereto. For example, the liner 410 may include silicon oxide. The liner 410 may cover each of sub-portions 401 of the seed layer 400.

Referring to FIG. 10, a dielectric layer 420 may be formed on the liner 410. The dielectric layer 420 may be formed by a plasma enhanced chemical vapor deposition (PECVD) process. In some embodiments, the material of the dielectric layer 420 may be the same as that of the liner 410. For example, the dielectric layer 420 may include silicon oxide. The step coverage of the dielectric layer 420 may be lower than that of the liner 410.

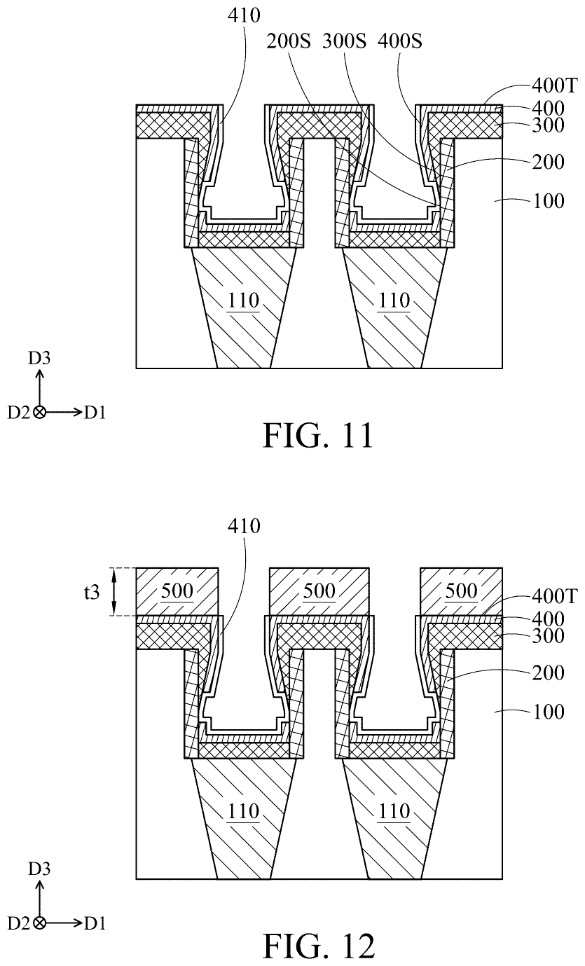

Referring to FIG. 11, a removal process may be performed to remove the dielectric layer 420 and the liner 410 to expose the top surface 400T of the seed layer 400. After the removal process, the liner 410 may cover the side surface 400S of the seed layer 400, the side surface 300S of the second barrier layer 300, and the side surface 200S of the first barrier layer 200. The removal process may be a chemical mechanical polishing (CMP) process. Accordingly, by sequentially forming the liner 410 and the dielectric layer 420, a removal process may be then performed to facilitate exposing the top surface 400T of the seed layer 400 (and covering the side surface 400S of the seed layer 400). In detail, since the liner 410 may be formed by the ALD process, the thickness of the liner 410 may be relatively thin. When the liner 410 may be single formed (without the dielectric layer 420), the subsequent CMP process may be not easy to receive a stop signal, thereby causing the problem of over-removal. In addition, since the dielectric layer 420 may be formed by PECVD, the thickness of the dielectric layer 420 may be relatively thick. When the dielectric layer 420 may be single formed (without the liner 410), the dielectric layer 420 may be sealed prematurely and the dielectric layer 420 cannot be conformally formed on the seed layer 400. Accordingly, by sequentially forming the liner 410 and the dielectric layer 420, the process margin of the formation method of the semiconductor device may be improved.

Referring to FIG. 12, after removing the dielectric layer 420 and the liner 410 to expose the top surface 400T of the seed layer 400, a target layer 500 may be formed on the top surface 400T of the seed layer 400. The target layer 500 may be formed on the seed layer 400 exposed by the liner 410. The target layer 500 may not be formed on the liner 410. The target layer 500 may be formed by an electroplating process, other suitable processes, or a combination thereof, but the present disclosure is not limited thereto. In the normal direction of the base layer 100, the target layer 500 may have a third thickness t3. Based on the aspect ratio of the trench 130 shown in FIG. 2, the third thickness t3 may be greater than or equal to 10 nm and less than or equal to 5000 nm. For example, the third thickness t3 may be 10 nm, 100 nm, 500 nm, 1000 nm, 2500 nm, 5000 nm, or any value or any range of values between the aforementioned values, but the present disclosure is not limited thereto.

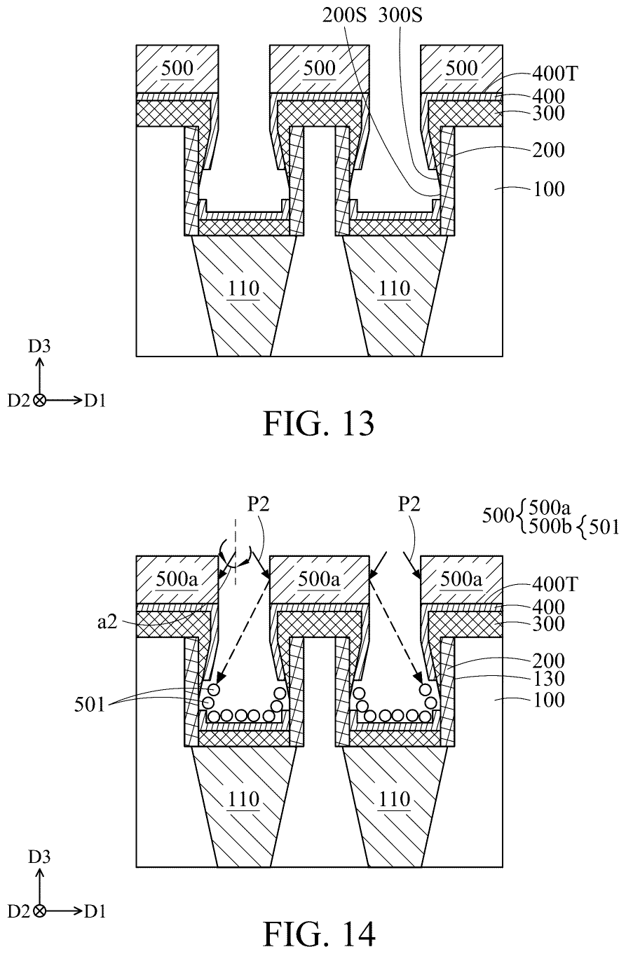

Referring to FIG. 13, after forming the target layer 500 on the top surface 400T of the seed layer 400, the liner 410 may be completely removed, in order to expose the side surface 400S of the seed layer 400, the side surface 300S of the second barrier layer 300, and the side surface 200S of the first barrier layer 200. The liner 410 may be removed by the wet etching.

Referring to FIG. 14, after completely removing the liner 410, a re-sputtering process P2 may be performed on the target layer 500. The re-sputtering process P2 may be performed on the target layer 500, so that the first portion 500a of the target layer 500 remains outside the trench 130, and the second portion 500b of the target layer 500 may be transferred into the trench 130. In some embodiments, the target layer 500 may be bombarded with a working gas, and the target material 501 of the target layer 500 may be knocked down into the trench 130. Wherein the target layer 500 located on the top surface 400T of the seed layer 400 may be compared to a target. The target material 501 may be deposited in the trench 130 and may be referred as the second portion 500b of the target layer 500. In addition, the target layer 500 had been bombarded by the working gas may be referred as the first portion 500a of the target layer 500. In other words, the target layer 500 located on the top surface 400T of the seed layer 400 may be redistributed into the trench 130 by the re-sputtering process P2. The target layer 500 may include a metal such as tungsten (W), copper (Cu), silver (Ag), gold (Au), and cobalt (Co). The target layer 500 may include a material having excellent compatibility with the material of the subsequently formed conductive pillar.

As shown in FIG. 14, in some embodiments, the re-sputtering angle a2 of the re-sputtering process P2 may be 0 to 45 degrees. The re-sputtering angle a2 may be the angle between the traveling direction of the working gas beam and the normal direction of the base layer 100. In some embodiments, the re-sputtering angle a2 may be 0 degrees, 5 degrees, 10 degrees, 15 degrees, 20 degrees, 25 degrees, 30 degrees, 35 degrees, 40 degrees, 45 degrees, or any value or any range of values between the aforementioned values, but the present disclosure is not limited thereto. In some embodiments, the working atoms of the re-sputtering process P2 may include copper (Cu), arsenic (As), indium (In), germanium (Ge), helium (He), neon (Ne), argon (Ar), krypton (Kr), xenon (Xe), radon (Rn), aluminum (Al), magnesium (Mg), or any combination thereof.

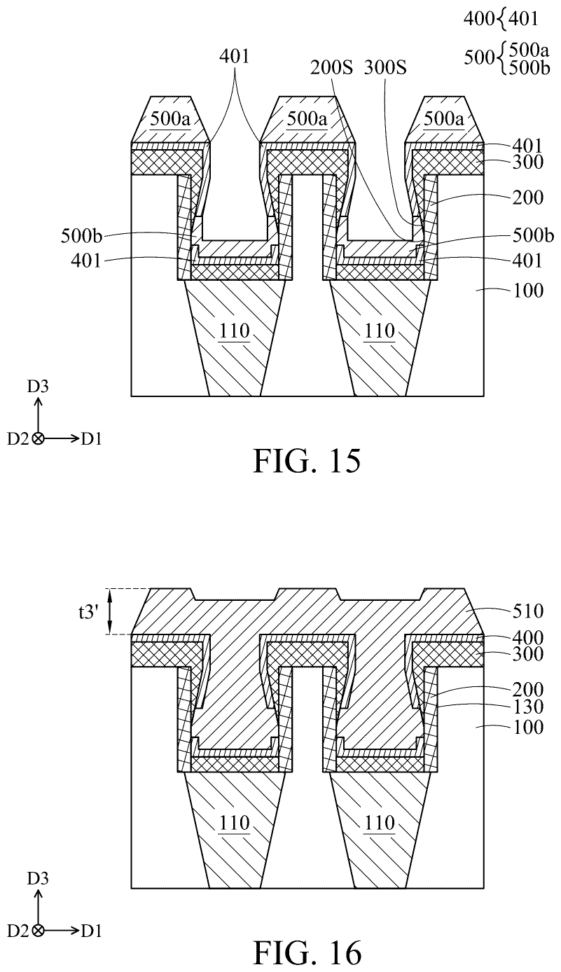

Referring to FIG. 15, the second portion 500b of the target layer 500 may connect the sub-portions 401 of the seed layer 400. Accordingly, the target layer 500 may improve the continuity and/or reliability of the seed layer 400. The second portion 500b of the target layer 500 may be in contact with the side surface 300S of the second barrier layer 300 and the side surface 200S of the first barrier layer 200. Accordingly, the electrical properties of the semiconductor device and the process margin of the formation method of the semiconductor device may be improved. In detail, the second portion 500b of the target layer 500 may be formed on the second barrier layer 300 and the first barrier layer 200 by the re-sputtering process P2. Even if the seed layer 400 may be disposed discontinuously, the second portion 500b may be disposed on the seed layer 400 first to facilitate the subsequent formation of the conductive pillar, thereby reducing defects such as voids and holes formed in the conductive pillar. That is, the re-sputtering process P2 may overcome the limitation that it is difficult to continuously form the seed layer 400, so the seed layer 400 and the target layer 500 may be widely used in trenches with different aspect ratios.

Referring to FIG. 16, in some embodiments, the re-sputtering process P2 may be performed continuously so that the second portion 500b of the target layer 500 completely fills the trench 130 to form a conductive pillar 510. In this embodiment, in the third direction D3, the thickness of the second portion 500b gradually increases, and the third thickness t3′ of the first portion 500a gradually decreases. The third thickness t3′ may be less than the third thickness t3. The third thickness t3′ may be greater than 0. In other embodiments, a reflow process may be performed on the first portion 500a and the second portion 500b of the target layer 500 to form the conductive pillar 510. For example, the reflow process may be performed at a temperature of 300° C. to 400° C. to heat the target layer 500 so as to redistribute the location of the material of the target layer 500. In this embodiment, the material of the conductive pillar 510 may be the same as the material of the target layer 500. For example, the conductive pillar 510 may include copper.

In other embodiments, since the seed layer 400 may be continuous, an electroplating process or other suitable process may be used to additionally fill other material on the target layer 500 to form the conductive pillar 510. In this embodiment, the material of the conductive pillar 510 may be the same as or different from the material of the target layer 500. In this embodiment, there may be a substantial interface between the conductive pillar 510 and the target layer 500.

Referring to FIG. 17, a planarization process may be performed to expose the top surface 100T of the base layer 100. Thus, the semiconductor device 1 may be obtained. The first barrier layer 200 and the second barrier layer 300 may be in directly contact with the top surface 110T of the conductive structure 110. The seed layer 400 may expose the side surface 200S of the first barrier layer 200, and the conductive pillar 510 may cover the exposed side surface 200S of the first barrier layer 200. The conductive pillar 510 may be in contact with the first barrier layer 200, the second barrier layer 300, and the seed layer 400. Since the second barrier layer 300 may expose the side surface 200S of the first barrier layer 200, the volume occupied by the second barrier layer 300 in the trench 130 may be reduced. Accordingly, the volume of the seed layer 400 and the conductive pillar 510 disposed in the trench 130 may be increased, and the on-resistance of the semiconductor device 1 may be reduced.

In some embodiments, the semiconductor device and formation method of the semiconductor device may be applied in DRAM. In some embodiments, the conductive structure 110 of the semiconductor device disclosed herein may be a zero metal layer (M0), a first metal layer (M1), a second metal layer (M2), or other conductive layers in the semiconductor device. In some embodiments, the base layer 100 of the semiconductor device disclosed herein may be an oxide layer covering a metal layer or other conductive layer.

In other embodiments (not shown), the semiconductor device may omit the conductive structure 110. In this embodiment, since the second barrier layer 300 does not need to be in contact with the conductive structure 110, the etching process shown in FIG. 5 may be omitted. In other words, in this embodiment, the first barrier layer 200 may be disposed on the bottom surface 130B and the side surface 130S of the trench 130, and the second barrier layer 300 may be disposed on the first barrier layer 200. In the cross-sectional view, the first barrier layer 200 may have a U-shaped profile.

In some other embodiments (not shown), the semiconductor device may omit one of the first barrier layer 200 and the second barrier layer 300, and the other of the first barrier layer 200 and the second barrier layer 300 may be conformally formed in the trench 130. Then, a discontinuous seed layer 400 may be disposed on the barrier layer, and a subsequent re-sputtering process P2 may be performed.

Accordingly, the present disclosure avoids unnecessary conduction, leakage current, and/or short circuit between adjacent elements by disposing a double barrier layer including a first barrier layer and a second barrier layer. In detail, the double barrier layer may prevent the metal atoms in the conductive pillar from diffusing into the conductive structure, the base layer, or other adjacent components below the conductive pillar, to prevent the electrical degradation of the conductive structure. For example, the first barrier layer may be a dielectric barrier layer formed by an implantation process, and the second barrier layer may be a metal barrier layer including metal atoms formed by a deposition process. For example, the first barrier layer may be formed at least on the side surface of the trench, and the second barrier layer may be formed at least on the bottom surface of the trench. Therefore, the combination of the first barrier layer and the second barrier layer may avoid being limited by the aspect ratio of the trench and/or reduce the on-resistance. In addition, since the first barrier layer may be a dielectric barrier layer formed by an implantation process, it will not occupy the space of the trench and cause the aspect ratio to increase, thereby defects such as gaps and holes formed in the conductive pillar may be prevented.

Furthermore, the present disclosure improves the continuity and/or reliability of the seed layer by transferring the target material of the target layer outside the trench into the trench. Thus, defects such as gaps and holes in the conductive pillars formed on the seed layer can be reduced to improve the reliability of the conductive pillars. In addition, the present disclosure controls the depth of the formed trenches so that the trenches and the conductive structures are separated from each other to avoid the implantation process from damaging the conductive structure. Accordingly, the present disclosure can improve the electrical properties of the semiconductor device and can improve the process margin of the method for forming the semiconductor device.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
providing a base layer;
forming a trench in the base layer;
performing an implantation process on the base layer to form a first barrier layer on a side surface of the trench;
forming a second barrier layer on the first barrier layer and on a bottom surface of the trench;
forming a seed layer on the second barrier layer; and
forming a conductive pillar on the seed layer.

2. The formation method as claimed in claim 1, wherein the first barrier layer comprises a nitride, a carbide, or a carbonitride of the base layer.

3. The formation method as claimed in claim 2, wherein the second barrier layer comprises a metal, a conductive metal nitride, or a conductive metal carbide.

4. The formation method as claimed in claim 1, wherein the seed layer comprises a plurality of sub-portions, and the sub-portions are physically separated from each other.

5. The formation method as claimed in claim 4, wherein the formation of the conductive pillar on the seed layer further comprises:
forming a target layer on the seed layer; and
performing a re-sputtering process on the target layer, so that a first portion of the target layer is located outside the trench and a second portion of the target layer is located inside the trench,
wherein the second portion of the target layer makes the sub-portions of the seed layer electrically connect with each other.

6. The formation method as claimed in claim 5, wherein the second portion of the target layer completely fills the trench to form the conductive pillar.

7. The formation method as claimed in claim 5, wherein the formation of the conductive pillar on the seed layer further comprises:
performing a reflow process on the target layer to form the conductive pillar.

8. The formation method as claimed in claim 5, wherein the formation of the seed layer on the second barrier layer further comprises:
forming the seed layer on the second barrier layer, wherein the seed layer exposes a side surface of the first barrier layer;
forming a liner on the seed layer;
forming a dielectric layer on the liner; and
removing the dielectric layer and the liner to expose the seed layer.

9. The formation method as claimed in claim 8, wherein after the removal of the dielectric layer and the liner, the target layer is formed on the seed layer.

10. The formation method as claimed in claim 9, wherein the formation of the seed layer on the second barrier layer further comprises:
before performing the re-sputtering process on the target layer, the liner is removed to expose the seed layer, the second barrier layer, and the first barrier layer.

11. The formation method as described in claim 1, wherein performing the implantation process on the base layer to form the first barrier layer on the side surface of the trench further comprises:
forming the first barrier layer on the side surface and the bottom surface of the trench; and
removing the first barrier layer to expose the bottom surface of the trench.

12. The formation method as claimed in claim 1, further comprising:
providing a conductive structure in the base layer, wherein the bottom surface of the trench is spaced a distance from a top surface of the conductive structure.

13. The formation method as claimed in claim 12, wherein the first barrier layer and the second barrier layer are in contact with the top surface of the conductive structure.

14. The formation method as claimed in claim 12, wherein a width of the conductive structure is greater than a width of the trench.

15. The formation method as claimed in claim 1, wherein an angle of the implantation process is 0 to 45 degrees.

16. The formation method as claimed in claim 1, wherein dopants of the implantation process are nitrogen atoms, carbon atoms, or a combination thereof.

17. A semiconductor device comprising:
a base layer;
a conductive structure disposed in the base layer;
a first barrier layer disposed in the base layer and on a portion of a top surface of the conductive structure;
a second barrier layer disposed in the base layer, disposed on the first barrier layer, and disposed on a remaining portion of the top surface of the conductive structure;
a seed layer disposed on the second barrier layer; and
a conductive pillar disposed on the seed layer.

18. The semiconductor device as claimed in claim 17, wherein the second barrier layer exposes a side surface of the first barrier layer.

19. The semiconductor device as claimed in claim 17, wherein the seed layer exposes a side surface of the first barrier layer, and the conductive pillar covers the exposed side surface of the first barrier layer.

20. The semiconductor device as claimed in claim 17, wherein the conductive pillar is in contact with the first barrier layer, the second barrier layer, and the seed layer.
